(19) United States
(12) Patent Application Publication
(10) Pub. No.: US 2009/0020771 A1
(43) Pub. Date: Jan. 22, 2009

(54) III-Nitride Semiconductor Light Emitting Device And Method For Manufacturing The Same

(75) Inventors: Chang-Tae Kim, Gyunggi-do (KR); Hyun-Min Jung, Gyunggi-do (KR); Eui-Gue Jeon, Chungcheongbuk-do (KR); Hyun-Suk Kim, Gyunggi-do (KR); Gi-Yeon Nam, Gyunggi-do (KR); Byeong-Kyun Choi, Gyunggi-do (KR)

Correspondence Address: HARNESS, DICKEY, & PIERCE, P.L.C, 7700 Bonhomme, Suite 400, ST. LOUIS, MO, 63105, US

(73) Assignee: EPIVALLEY CO., LTD., Gyungbuk (KR)

(21) Appl. No.: 12/196,000

(22) Filed: Aug. 21, 2008

Related U.S. Application Data
(63) Continuation of application No. PCT/KR2006/005755, filed on Dec. 27, 2006.

(30) Foreign Application Priority Data
Apr. 18, 2006 (KR) 10-2006-0035149
Aug. 31, 2006 (KR) 10-2006-0083404

(51) Int. Cl. H01L 33/00

(52) U.S. Cl. 257/94; 438/44; 257/E33.027

(57) ABSTRACT

The present disclosure relates to an III-nitride compound semiconductor light emitting device and a method of manufacturing the same. The III-nitride compound semiconductor light emitting device includes a substrate with a groove formed therein, a plurality of nitride compound semiconductor layers being grown on the substrate, and including an active layer for generating light by recombination of electron and hole, and an opening formed on the groove along the plurality of nitride compound semiconductor layers.

### CROSS-REFERENCE TO RELATED APPLICATIONS

This application is a continuation of PCT International Application PCT/KR20061005755 filed Dec. 27, 2006. This application claims the benefit of Korean Patent Application No. 10-2006-0035149 filed Apr. 18, 2006 and Korean Patent Application No. 10-2006-0083404 filed Aug. 31, 2006. The entire disclosures of the above applications are incorporated herein by reference.

### FIELD

The present disclosure generally relates to a III-nitride semiconductor light emitting device and a method of manufacturing the same, and more particularly, to a III-nitride semiconductor light emitting device manufactured by forming a groove in a sapphire substrate, forming a plurality of nitride compound semiconductor layers thereon, and connecting an electrode to the plurality of nitride compound semiconductor layers through the groove, and a method of manufacturing the same.

### BACKGROUND

This section provides background information related to the present disclosure which is not necessarily prior art.

FIG. 1 is a cross-sectional view illustrating one example of a conventional III-nitride (compound) semiconductor light emitting device. The conventional semiconductor light emitting device includes a substrate 100, a buffer layer 200 epitaxially grown on the substrate 100, an n-type nitride compound semiconductor layer 300 epitaxially grown on the buffer layer 200, an active layer 400 epitaxially grown on the n-type nitride compound semiconductor layer 300, a p-type nitride compound semiconductor layer 500 epitaxially grown on the active layer 400, a p-side electrode 600 formed on the p-type nitride compound semiconductor layer 500, a p-side bonding pad 700 formed on the p-side electrode 600, and an n-side electrode 800 formed on the n-type nitride compound semiconductor layer 301 exposed by mesa-etching at least the p-type nitride compound semiconductor layer 500 and the active layer 400.

In the case of the substrate 100, a GaN substrate can be used as a same kind substrate, and a sapphire substrate, an SiC substrate or an Si substrate can be used as a different kind substrate. Any kind of substrate on which the nitride compound semiconductor layer can be grown can be used. If the SiC substrate is used, the n-side electrode 800 can be formed at the side of the SiC substrate.

The nitride compound semiconductor layers epitaxially grown on the substrate 100 are mostly grown by the metal organic chemical vapor deposition (MOCVD).

The buffer layer 200 serves to overcome differences in lattice parameter and thermal expansion coefficient between the different kind substrate 100 and the nitride compound semiconductor. U.S. Pat. No. 5,122,845 mentions a method for growing an AlN buffer layer having a thickness of 100 to 500 Å on a sapphire substrate at 380 to 800° C. U.S. Pat. No. 5,290,393 suggests a method for growing an Al₍ₓ₎Ga₍₁₋ₓ₎N (0≦x<1) buffer layer having a thickness of 10 to 5000 A on a sapphire substrate at 200 to 900° C. Korea Patent 10-0448352 mentions a method for growing a SiC buffer layer at 600 to 990° C., and growing an In₍ₓ₎Ga₍₁₋ₓ₎N (0<x≦1) layer thereon.

In the n-type nitride compound semiconductor layer 300, at least the n-side electrode 800 formed region (n-type contact layer) is doped with a dopant. Preferably, the n-type contact layer is made of GaN and doped with Si. U.S. Pat. No. 5,733,796 teaches a method for doping an n-type contact layer at a target doping concentration by controlling a mixture ratio of Si and a source material.

The active layer 400 generates light quanta (light) by recombination of electrons and holes. Normally, the active layer 400 is made of In₍ₓ₎Ga₍₁₋ₓ₎N (0<x≦1) and comprised of single or multi well layers. WO 02/021121 suggests a method for partially doping a plurality of quantum well layers and barrier layers. The p-type nitride compound semiconductor layer 500 is doped with an appropriate dopant such as Mg, and provided with p-type conductivity by activation. U.S. Pat. No. 5,247,533 mentions a method for activating a p-type nitride compound semiconductor layer by electron beam radiation. U.S. Pat. No. 5,306,662 teaches a method for activating a p-type nitride compound semiconductor layer by annealing over 400° C. Also, Korean Patent 10-043346 suggests a method for endowing a p-type nitride compound semiconductor layer with p-type conductivity without activation, by using NH₃ and a hydrogen group source material as a nitrogen precursor for the growth of the p-type nitride compound semiconductor layer.

The p-side electrode 600 facilitates current supply to the whole p-type nitride compound semiconductor layer 500. U.S. Pat. No. 5,563,422 mentions a light transmitting electrode formed almost on the whole surface of a p-type nitride compound semiconductor layer to ohmic-contact the p-type nitride compound semiconductor layer, and composed of Ni and Au. U.S. Pat. No. 6,515,306 suggests a method for forming an n-type super lattice layer on a p-type nitride compound semiconductor layer, and forming a light transmitting electrode made of ITO thereon. Meanwhile, the p-side electrode 600 can be formed thick not to transmit light, namely, to reflect light to the substrate side. A light emitting device using the p-side electrode 600 is called a flip chip. U.S. Pat. No. 6,194,743 teaches an electrode structure including an Ag layer having a thickness over 20 nm, a diffusion barrier layer for covering the Ag layer, and a bonding layer made of Au and Al for covering the diffusion barrier layer.

The p-side bonding pad 700 and the n-side electrode 800 are formed for current supply and external wire bonding. U.S. Pat. No. 5,563,422 suggests a method for forming an n-side electrode with Ti and Al, and U.S. Pat. No. 5,652,434 suggests a method for making a p-side bonding pad contact a p-type nitride compound semiconductor layer by removing a part of a light transmitting electrode.

The conventional III-nitride compound semiconductor light emitting device mostly uses sapphire which is an insulator as the substrate 100. As a result, the p-side electrode 600, the p-side bonding pad 700 and the n-side electrode 800 must be formed in the same side.

FIG. 2 is a cross-sectional view illustrating an III-nitride compound semiconductor light emitting device described in Korea Patent Laid-Open Gazette 2005-078661. The light emitting device is manufactured by forming a plurality of nitride compound semiconductor layers on a substrate, forming a via 900 by polishing and etching the rear surface of the substrate, and forming an electrode through the via 900.

### SUMMARY

This section provides a general summary of the disclosure, and is not a comprehensive disclosure of its full scope or all of its features.

According to one aspect of the present disclosure, a method of manufacturing a III-nitride compound semiconductor light emitting device includes a substrate having a first surface and a second surface opposite to the first surface; a plurality of nitride compound semiconductor layers being grown on the first surface side of the substrate, and including a first nitride compound semiconductor layer with first conductivity, a second nitride compound semiconductor layer with second conductivity different from the first conductivity, and an active layer interposed between the first nitride compound semiconductor layer and the second nitride compound semiconductor layer, for generating light by recombination of electron and hole; a first electrode electrically connected to the first nitride compound semiconductor layer; and a second electrode electrically connected to the second nitride compound semiconductor layer; the method comprising: a first step for forming a groove on the first surface of the substrate; a second step for growing the plurality of nitride compound semiconductor layers on the first surface side of the substrate with the groove formed therein; a third step for partially removing the substrate from the second surface side of the substrate so that the first electrode can be electrically connected to the first nitride compound semiconductor layer through the groove; and a fourth step for forming the first electrode from the second surface side of the substrate so that the first electrode can be electrically connected to the first nitride compound semiconductor layer through the groove.

According to another aspect of the present disclosure, a III-nitride compound semiconductor light emitting device comprises a sapphire substrate having a first surface, a second surface opposite to the first surface, and a groove extended from the first surface to the second surface; a plurality of nitride compound semiconductor layers being grown at the first surface side of the sapphire substrate, and including a first nitride compound semiconductor layer with first conductivity, a second nitride compound semiconductor layer with second conductivity different from the first conductivity, and an active layer interposed between the first nitride compound semiconductor layer and the second nitride compound semiconductor layer, for generating light by recombination of electron and hole, an opening being formed to communicate with the groove; a first electrode electrically connected from the second surface of the sapphire substrate to the first nitride compound semiconductor layer through the groove; and a second electrode electrically connected to the second nitride compound semiconductor layer.

According to another aspect of the present disclosure, a III-nitride compound semiconductor light emitting device comprises a substrate having a first surface, a second surface opposite to the first surface, and a groove extended from the first surface to the second surface; a plurality of nitride compound semiconductor layers being grown on the first surface side of the substrate, and including a first nitride compound semiconductor layer with first conductivity, a second nitride compound semiconductor layer with second conductivity different from the first conductivity, and an active layer interposed between the first nitride compound semiconductor layer and the second nitride compound semiconductor layer, for generating light by recombination of electron and hole; a first electrode electrically connected from the second surface of the substrate to the first nitride compound semiconductor layer through the groove, and formed on the whole second surface of the substrate as a reflecting film; and a second electrode electrically connected to the second nitride compound semiconductor layer.

According to another aspect of the present disclosure, a III-nitride compound semiconductor light emitting device comprises a substrate with a groove formed therein; a plurality of nitride compound semiconductor layers being grown over the substrate, and including an active layer for generating light by recombination of electron and hole; and an opening formed on the groove along the plurality of nitride compound semiconductor layers.

According to another aspect of the present disclosure, a III-nitride compound semiconductor light emitting device comprises a substrate with a groove and a scribing line formed along the groove; and a plurality of nitride compound semiconductor layers being grown over the substrate, and including an active layer for generating light by recombination of electron and hole.

Further areas of applicability will become apparent from the description provided herein. The description and specific examples in this summary are intended for purposes of illustration only and are not intended to limit the scope of the present disclosure.

### DESCRIPTION OF DRAWINGS

FIG. 1 is a cross-sectional view illustrating one example of a conventional III-nitride compound semiconductor light emitting device;

FIG. 2 is a cross-sectional view illustrating a III-nitride compound semiconductor light emitting device described in Korea Patent Laid-Open Gazette 2005-078661;

FIG. 3 is an explanatory view illustrating one step for manufacturing a III-nitride compound semiconductor light emitting device in accordance with an embodiment of the present disclosure;

FIG. 4 is a photograph showing a substrate with grooves formed therein by a laser;

FIG. 5 is an explanatory view illustrating another step for manufacturing the III-nitride compound semiconductor light emitting device in accordance with an embodiment of the present disclosure;

FIG. 6 is a photograph showing a plurality of nitride compound semiconductor layers grown on a substrate with grooves formed therein;

FIG. 7 is a cross-sectional view taken along line A-A′ of FIG. 6;

FIG. 8 is an explanatory view illustrating yet another steps for manufacturing the III-nitride compound semiconductor light emitting device in accordance with an embodiment of the present disclosure;

FIG. 9 is a cross-sectional view illustrating one example of the III-nitride compound semiconductor light emitting device in accordance with an embodiment of the present disclosure;

FIG. 10 is photographs showing the front and rear surfaces of the III-nitride compound semiconductor light emitting device in accordance with an embodiment of the present disclosure;

FIG. 11 is a photograph showing an example of a substrate with grooves and scribing lines formed therein in accordance with an embodiment of the present disclosure; and

FIG. 12 is a photograph showing a plurality of nitride compound semiconductor layers grown on a substrate with grooves and scribing lines formed therein in accordance with an embodiment of the present disclosure.

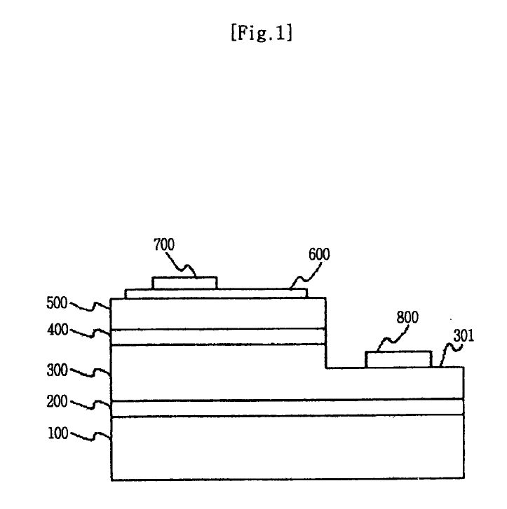

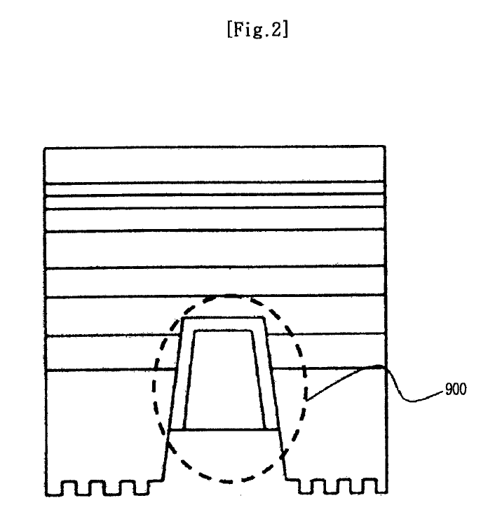

### DETAILED DESCRIPTION

The present disclosure is to provide a III-nitride semiconductor light emitting device and a method of manufacturing the same.

In an embodiment of the present disclosure is to provide a III-nitride compound semiconductor light emitting device which includes a substrate with a groove formed therein, and a method of manufacturing the same.

In another embodiment of the present disclosure is to provide an III-nitride compound semiconductor light emitting device in which an opening is formed in a plurality of nitride compound semiconductor layers along the groove, and a method of manufacturing the same.

There is provided a method of manufacturing a III-nitride compound semiconductor light emitting device including: a substrate having a first surface and a second surface opposite to the first surface; a plurality of nitride compound semiconductor layers being grown on the first surface side of the substrate, and including a first nitride compound semiconductor layer with first conductivity, a second nitride compound semiconductor layer with second conductivity different from the first conductivity, and an active layer interposed between the first nitride compound semiconductor layer and the second nitride compound semiconductor layer, for generating light by recombination of electron and hole! a first electrode electrically connected to the first nitride compound semiconductor layer; and a second electrode electrically connected to the second nitride compound semiconductor layer; the method including: a first step for forming a groove on the first surface of the substrate; a second step for growing the plurality of nitride compound semiconductor layers on the first surface side of the substrate with the groove formed therein; a third step for partially removing the substrate from the second surface side of the substrate so that the first electrode can be electrically connected to the first nitride compound semiconductor layer through the groove; and a fourth step for forming the first electrode from the second surface side of the substrate so that the first electrode can be electrically connected to the first nitride compound semiconductor layer through the groove. According to the above method, the vertical structure type light emitting device in which the electrodes are positioned at the upper and lower portions of the plurality of III-nitride compound semiconductor layers can be manufactured without removing the whole substrate. The opening may be or may not be formed under the growth conditions of the nitride compound semiconductor layers. Meanwhile, according to the design specification, it is necessary to form the groove over a predetermined size so as to stably connect the first electrode to the first nitride compound semiconductor layer through the groove. However, if the groove is large, it is difficult to form the opening. In accordance with the present disclosure, the vertical structure type III-nitride compound semiconductor light emitting device can be manufactured regardless of the limitations in design.

In another aspect of the present disclosure, there is provided a III-nitride compound semiconductor light emitting device, including: a sapphire substrate having a first surface, a second surface opposite to the first surface, and a groove extended from the first surface to the second surface; a plurality of nitride compound semiconductor layers being grown at the first surface side of the sapphire substrate, and including a first nitride compound semiconductor layer with first conductivity, a second nitride compound semiconductor layer with second conductivity different from the first conductivity, and an active layer interposed between the first nitride compound semiconductor layer and the second nitride compound semiconductor layer, for generating light by recombination of electron and hole, an opening being formed to communicate with the groove; a first electrode electrically connected from the second surface of the sapphire substrate to the first nitride compound semiconductor layer through the groove; and a second electrode electrically connected to the second nitride compound semiconductor layer.

In another aspect of the present disclosure, the first nitride compound semiconductor layer is exposed in the opening, and the first electrode is formed on the exposed first nitride compound semiconductor layer. In yet another aspect of the present disclosure, the first electrode is formed on the whole second surface of the sapphire substrate as a reflecting film.

In yet another aspect of the present disclosure, there is provided a III-nitride compound semiconductor light emitting device, including: a substrate having a first surface, a second surface opposite to the first surface, and a groove extended from the first surface to the second surface; a plurality of nitride compound semiconductor layers being grown on the first surface side of the substrate, and including a first nitride compound semiconductor layer with first conductivity, a second nitride compound semiconductor layer with second conductivity different from the first conductivity, and an active layer interposed between the first nitride compound semiconductor layer and the second nitride compound semiconductor layer, for generating light by recombination of electron and hole! a first electrode electrically connected from the second surface of the substrate to the first nitride compound semiconductor layer through the groove, and formed on the whole second surface of the substrate as a reflecting film; and a second electrode electrically connected to the second nitride compound semiconductor layer.

In yet another aspect of the present disclosure, a substrate with a groove formed therein; a plurality of nitride compound semiconductor layers being grown over the substrate, and including an active layer for generating light by recombination of electron and hole; and an opening formed on the groove along the plurality of nitride compound semiconductor layers.

In yet another aspect of the present disclosure, the plurality of nitride compound semiconductor layers include a nitride compound semiconductor layer exposed by etching, and the first electrode electrically contacts the exposed nitride compound semiconductor layer.

In yet another aspect of the present disclosure, the substrate includes a scribing line formed on the groove.

In yet another aspect of the present disclosure, the opening is formed on the scribing line.

In yet another aspect of the present disclosure, the III-nitride compound semiconductor light emitting device includes a step in the opening.

In yet another aspect of the present disclosure, the III-nitride compound semiconductor light emitting device includes a plurality of openings and a bonding pad positioned between the plurality of openings.

In yet another aspect of the present disclosure, a substrate with a groove and a scribing line formed along the groove; and a plurality of nitride compound semiconductor layers being grown over the substrate, and including an active layer for generating light by recombination of electron and hole.

The III-nitride compound semiconductor light emitting device includes an opening formed over the groove along the plurality of nitride compound semiconductor layers.

In accordance with the III-nitride compound semiconductor light emitting device, the current can be uniformly diffused in the light emitting device.

In accordance with the III-nitride compound semiconductor light emitting device, the vertical structure type light emitting device can be manufactured without separating the substrate from the plurality of III-nitride compound semiconductor layers.

The present disclosure will now be described in detail with reference to the accompanying drawings.

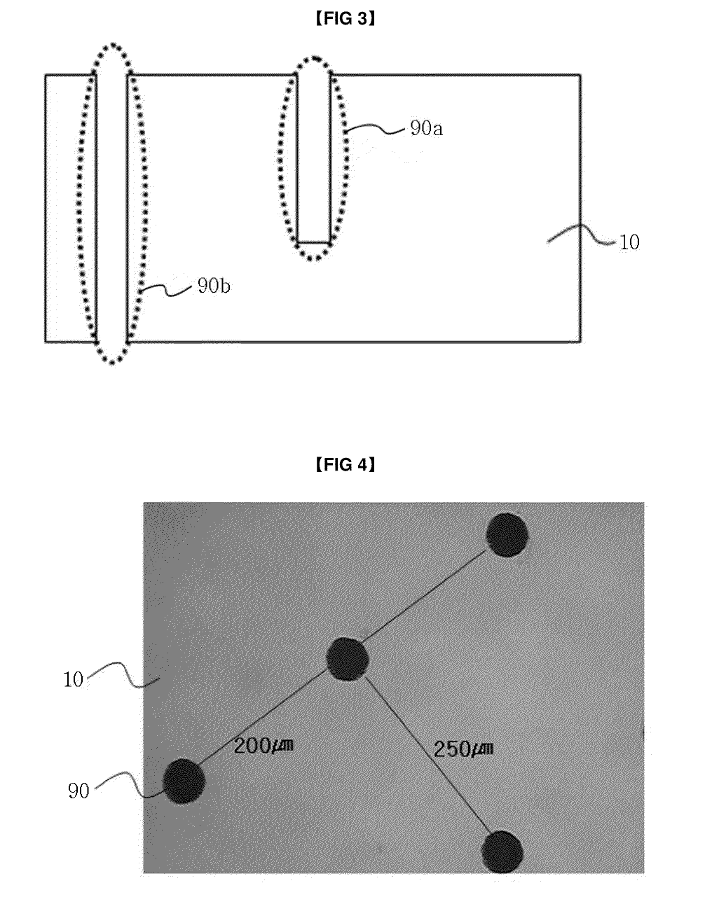

FIG. 3 is an explanatory view illustrating one step for manufacturing the III-nitride compound semiconductor light emitting device in accordance with the present disclosure. Grooves 90a and 90b are formed in a sapphire substrate 10 having a first surface and a second surface opposite to the first surface.

The grooves 90a and 90b are formed in the substrate 10 from the first surface toward the second surface by using a laser. In a state where the laser is focused, the grooves 90a and 90b can be formed in various circular, elliptical or polygonal shapes with a diameter of a few to a few hundreds μm. The depth of the grooves 90a and 90b can be determined according to changes of the conditions such as energy of the laser, an irradiation time of the laser, etc. The groove 90b can be formed to pass through the substrate 10. In the case of the groove 90b completely perforated through the substrate 10, it may be difficult to form the groove 90b to vertically pass through the substrate 10.

FIG. 4 is a photograph showing a state where grooves are formed in a substrate by using a laser, particularly, a surface observed through an optical microscope with a magnification of 200 times. In this photograph, circular grooves 90 with a diameter of 30 μm are formed in a substrate 10. The grooves 90 are arranged at periodical intervals of 200 μm in the x axis direction and 250 μm in the y axis direction from one groove 90. A diode pumped solid state (DPSS) laser with an active medium of neodymium-doped yttrium aluminum garnet (Nd:YAG) and a wavelength of 532 nm is used to form the grooves 90. Here, an output of the laser is 10 W (10 to 100 KHz) and a drilling speed is 20 to 50 holes/sec. After the grooves 90 are formed by using the laser, in order to remove generated impurities, the substrate 10 is organic-washed by using a phosphoric acid.

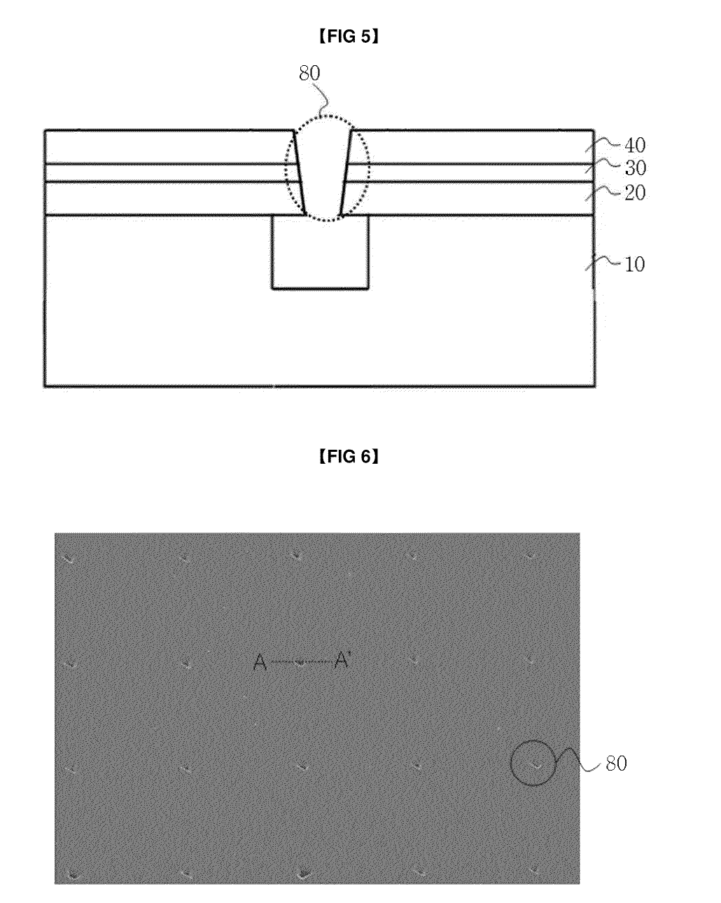

FIG. 5 is an explanatory view illustrating another step for manufacturing the III-nitride compound semiconductor light emitting device in accordance with the present disclosure, particularly, a schematic view illustrating a substrate 10 with a groove formed therein, an n-type nitride compound semiconductor layer 20 formed on a first surface of the substrate 10 with the groove formed therein, an active layer 30 grown on the n-type nitride compound semiconductor layer 20, and a p-type nitride compound semiconductor layer 40 grown on the active layer 30. The plurality of grown nitride compound semiconductor layers are nothing but an example of the present disclosure. It must be recognized that the present disclosure includes slight change of an epitaxial structure or addition/omission of an epitaxial layer.

The n-type nitride compound semiconductor layer 20 is made of GaN, and an n-type impurity is doped thereon. Si is used as the n-type impurity. A doping concentration of the impurity ranges from 1×10¹⁷ to 1×10²⁰/cm³. If the doping concentration is below 1×10¹⁷/cm³, ohmic contact may not be expected due to high resistance of the semiconductor layer 20, and if the doping concentration is over 1×10²⁰/cm³, the crystallinity of the semiconductor layer 20 may be deteriorated.

Preferably, a thickness of the n-type nitride compound semiconductor layer 20 ranges from 2 to 6 μm. If the thickness of the semiconductor layer 20 is over 6 μm, the crystallinity of the semiconductor layer 20 may be reduced to cause the detrimental effect on the device, and if the thickness is below 2 μm, electrons may not be smoothly supplied. Preferably, a growth temperature of the n-type nitride compound semiconductor layer 20 ranges from 600 to 1100° C. If the growth temperature is below 600° C., the crystallinity of the semiconductor layer 20 may be deteriorated, and if the growth temperature is over 1100° C., the surface of the semiconductor layer 20 may be roughened to cause the detrimental effect on the crystallinity of the semiconductor layer 20.

The n-type nitride compound semiconductor layer 20 is grown by 4 μm, by supplying TMGa, NH₃ and SiH₄ by 365 sccm, 11 slm, and 8.5 slm, respectively. Here, a growth temperature is 1050° C., a doping concentration is 3×10¹⁸/cm³, and a pressure of a reactor is 400 torr.

In the above growth conditions, the n-type nitride compound semiconductor layer 20 is not sufficiently grown in the lateral direction due to the deficient growth speed and the relatively low growth temperature. Accordingly, the n-type nitride compound semiconductor layer 20 does not cover the groove formed in the substrate 10 but forms an opening 80. In addition, the plurality of nitride compound semiconductor layers formed on the n-type nitride compound semiconductor layer 20 are not grown in the lateral direction either, so that the opening 80 reaches the topmost layer of the plurality of nitride compound semiconductor layers. A buffer layer may be grown before the growth of the n-type nitride compound semiconductor layer 20. Since the buffer layer is thin, it does not cover the opening 80.

The active layer 30 grown on the n-type nitride compound semiconductor layer 20 generates light by recombination of electron and hole. The active layer 30 can have a single or multi quantum well structure.

The p-type nitride compound semiconductor layer 40 grown on the active layer 30 is made of GaN, and a p-type impurity is doped thereon. Mg is used as the p-type impurity. A doping concentration of the impurity ranges from 1×10¹⁷ to 1×10²⁰/cm³. If the doping concentration is below 1×10¹⁷/cm³, the p-type nitride compound semiconductor layer 40 may not be normally operated, and if the doping concentration is over 1×10²⁰/cm³, the crystallinity of the semiconductor layer 40 may be deteriorated.

Preferably, a thickness of the p-type nitride compound semiconductor layer 40 ranges from 200 to 3000 Å. If the thickness of the semiconductor layer 40 is over 3000 Å, the crystallinity of the semiconductor layer 40 may be reduced to cause the detrimental effect on the device, and if the thickness is below 200 Å, holes may not be smoothly supplied. Preferably, a growth temperature of the p-type nitride compound semiconductor layer 40 ranges from 600 to 1100° C. If the growth temperature is below 600° C., the crystallinity of the semiconductor layer 40 may be deteriorated, and if the growth temperature is over 1100° C., the surface of the semiconductor layer 40 may be roughened to cause the detrimental effect on the crystallinity of the semiconductor layer 40.

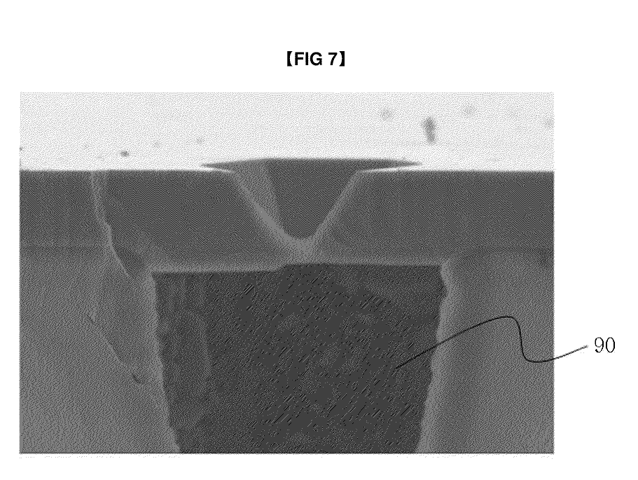

FIG. 6 is a photograph showing a plurality of nitride compound semiconductor layers grown on a substrate with grooves formed therein, particularly, the surface of the topmost layer of the plurality of nitride compound semiconductor layers observed through a scanning electron microscope. The plurality of nitride compound semiconductor layers are grown in the lateral direction to form openings 80. As shown in FIG. 7, the opening 80 is connected to the groove 90 formed in the substrate. FIG. 7 is a cross-sectional view taken along line A-A′ of FIG. 6.

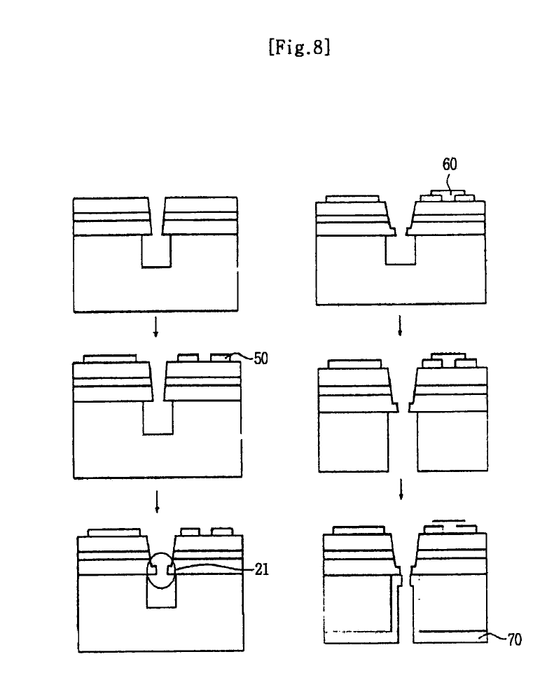

FIG. 8 is an explanatory view illustrating yet another step for manufacturing the III-nitride compound semiconductor light emitting device in accordance with the present disclosure. A plurality of nitride compound semiconductor layers including an active layer for generating light by recombination of electron and hole are grown on a substrate with a groove formed therein.

After the plurality of nitride compound semiconductor layers are grown, a p-side electrode 50 is formed on the plurality of nitride compound semiconductor layers. The pi-side electrode 50 contains any one selected from the group consisting of Ni, Au, Ag, Cr, Ti, Pt, Pd, Rh, Ir, Al, Sn, ITO, IZO, ZnO, ClO, In, Ta, Cu, Co, Fe, Ru, Zr, W and Mo.

After the p-side electrode 50 is formed, a process of exposing the n-type nitride compound semiconductor layer is carried out. Here, the n-type nitride compound semiconductor layer is exposed by dry etching and/or wet etching. In order to increase the exposed surface area, the n-type nitride compound semiconductor layer is preferably etched to have one step 21.

After the etching process of exposing the n-type nitride compound semiconductor layer, a p-side bonding pad 60 is formed at the upper portions of the p-side electrode 50 and the p-type nitride compound semiconductor layer. Therefore, a process of polishing a second surface of the substrate is performed. The substrate is polished to at least the groove formed region so that the groove can pass through the substrate. At this point, the substrate can be polished by grinding or wrapping. After the second surface of the substrate is polished, a final thickness of the substrate ranges preferably from 50 to 400 μm, and more preferably from 30 to 300 μm. If the final thickness of the substrate is below 30 μm, the substrate may be broken in a succeeding process, and if the final thickness of the substrate is over 300 μm, the vertical structure type light emitting device may not be much improved in brightness and thermal characteristic.

Before the second surface of the substrate is polished, a passivation film can be formed on the whole surface of the light emitting device except the p-side bonding pad 60. The passivation film is made of SiOₓ, SiNₓ, SiON, BCB or polyimide.

After the second surface of the substrate is polished, an n-side electrode 70 is formed. The n-side electrode 70 is formed on the second surface of the polished substrate to contact the n-type nitride compound semiconductor layer through the groove. The n-side electrode 70 can be formed by sputtering, E-beam evaporation or thermal deposition. The n-side electrode 70 contains any one selected from the group consisting of Ni, Au, Ag, Cr, Ti, Pt, Pd, Rh, Ir, Al, Sn, In, Ta, Cu, Co, Fe, Ru, Zr, W and Mo, or a combination thereof, and serves as a reflecting film. The n-side electrode 70 formed on the second surface of the substrate serves as an n-side bonding pad to apply the current to the semiconductor light emitting device.

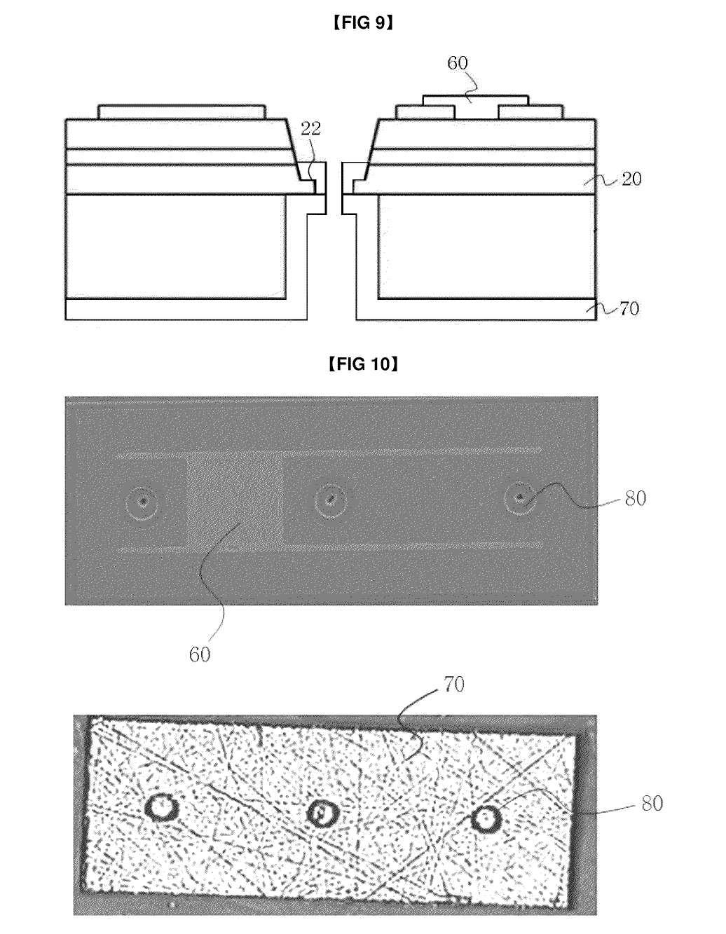

During the formation of the n-side electrode 70, a metal layer can be formed on the n-type nitride compound semiconductor layer 21 exposed to the opening in deposition of the p-side bonding pad 60. In addition, since the n-side electrode 70 is formed through the groove formed on the second surface of the substrate, the metal layer can be formed in the whole region of the exposed n-type nitride compound semiconductor layer 22, which is shown in FIG. 9.

FIG. 10 is photographs showing the front and rear surfaces of the III-nitride compound semiconductor light emitting device in accordance with the present disclosure. The light emitting device has a size of 600×250 μm. Three openings 80 are formed in the light emitting device.

The p-side bonding pad 60 is formed between the openings 80 in consideration of light emitting efficiency and current supply. The n-side electrode 70 is formed on the second surface of the polished substrate (which is shown in FIG. 10). In accordance with the present disclosure, the size of the light emitting device and the number of the openings 80 are not limited thereto. The position of the p-side bonding pad 60 is not limited to the space between the opening 80.

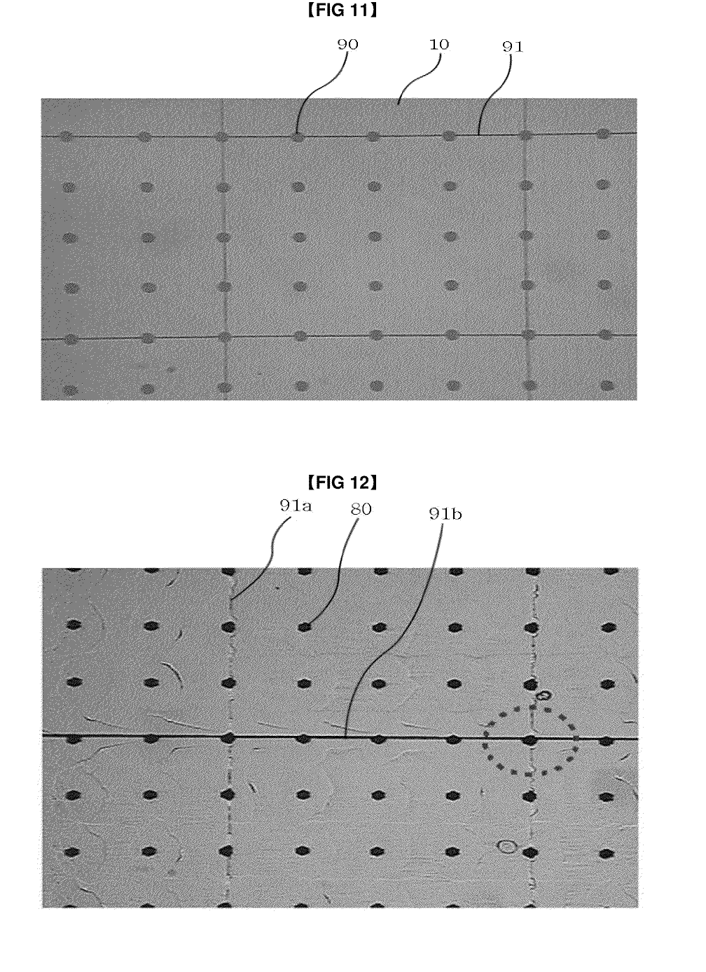

FIG. 11 is a photograph showing an example of a substrate with grooves and scribing lines formed therein in accordance with the present disclosure, particularly, a 50× microscope photograph showing the substrate undergoing a laser drilling process and a laser scribing process. Grooves 90 and scribing lines 91 are formed in a substrate 10.

FIG. 12 is a photograph showing a plurality of nitride compound semiconductor layers grown on a substrate with grooves and scribing lines formed therein, particularly, the surface of the topmost layer of the plurality of nitride compound semiconductor layers observed through an optical microscope. The plurality of nitride compound semiconductor layers are grown in the lateral direction to form openings 80. Moreover, different nitride compound semiconductor epitaxial growths are shown between laser scribing lines 91a vertical to a flat zone of the substrate and laser scribing lines 91b horizontal thereto. Especially, a nitride compound semiconductor growth speed is higher in the vertical direction than the horizontal direction, so that the vertical laser scribing lines 91a are almost covered.

A chip is formed by manufacturing a wafer by growing the plurality of nitride compound semiconductor layers on the substrate 10 with the scribing lines 91 formed along the grooves 90, and breaking the wafer. Accordingly, the number of the openings 80 existing in each chip (each light emitting device) can be reduced. It means that the light emitting device can be manufactured with a wider light emitting area. If the light emitting area is an important consideration in design of the light emitting device, this configuration gets more advantageous.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

What is claimed:

1. A method of manufacturing a III-nitride compound semiconductor light emitting device including:
a substrate having a first surface and a second surface opposite to the first surface;
a plurality of nitride compound semiconductor layers being grown on the first surface side of the substrate, and including a first nitride compound semiconductor layer with first conductivity, a second nitride compound semiconductor layer with second conductivity different from the first conductivity, and an active layer interposed between the first nitride compound semiconductor layer and the second nitride compound semiconductor layer, for generating light by recombination of electron and hole;
a first electrode electrically connected to the first nitride compound semiconductor layer; and a second electrode electrically connected to the second nitride compound semiconductor layer;
the method comprising:
a first step for forming a groove on the first surface of the substrate;
a second step for growing the plurality of nitride compound semiconductor layers on the first surface side of the substrate with the groove formed therein;
a third step for partially removing the substrate from the second surface side of the substrate so that the first electrode can be electrically connected to the first nitride compound semiconductor layer through the groove; and
a fourth step for forming the first electrode from the second surface side of the substrate so that the first electrode can be electrically connected to the first nitride compound semiconductor layer through the groove.

2. The method of claim 1, wherein, in the first step, the groove is formed not to perforate the substrate.

3. The method of claim 1, prior to the fourth step, further comprising a step for forming the first electrode from the first surface side of the substrate.

4. The method of claim 3, wherein the step further comprises a process of etching the plurality of nitride compound semiconductor layers from the first surface side of the substrate to expose the first nitride compound semiconductor layer, before forming the first electrode from the first surface side of the substrate.

5. The method of claim 1, wherein, in the fourth step, the first electrode is formed on the whole second surface of the substrate as a reflecting film.

6. The method of claim 1, wherein, in the second step, the plurality of nitride compound semiconductor layers are grown to form an opening which is formed at the upper portion of the groove.

7. The method of claim 1, wherein the substrate is a sapphire substrate.

8. A III-nitride compound semiconductor light emitting device, comprising:
a sapphire substrate having a first surface, a second surface opposite to the first surface, and a groove extended from the first surface to the second surface;
a plurality of nitride compound semiconductor layers being grown at the first surface side of the sapphire substrate, and including a first nitride compound semiconductor layer with first conductivity, a second nitride compound semiconductor layer with second conductivity different from the first conductivity, and an active layer interposed between the first nitride compound semiconductor layer and the second nitride compound semiconductor layer, for generating light by recombination of electron and hole, an opening being formed to communicate with the groove;
a first electrode electrically connected from the second surface of the sapphire substrate to the first nitride compound semiconductor layer through the groove; and
a second electrode electrically connected to the second nitride compound semiconductor layer.

9. The III-nitride compound semiconductor light emitting device of claim 8, wherein the first nitride compound semiconductor layer is exposed in the opening, and the first electrode is formed on the exposed first nitride compound semiconductor layer.

10. The III-nitride compound semiconductor light emitting device of claim 8, wherein the first electrode is formed on the whole second surface of the sapphire substrate as a reflecting film.

11. A III-nitride compound semiconductor light emitting device, comprising:
a substrate having a first surface, a second surface opposite to the first surface, and a groove extended from the first surface to the second surface;
a plurality of nitride compound semiconductor layers being grown on the first surface side of the substrate, and including a first nitride compound semiconductor layer with first conductivity, a second nitride compound semiconductor layer with second conductivity different from the first conductivity, and an active layer interposed between the first nitride compound semiconductor layer and the second nitride compound semiconductor layer, for generating light by recombination of electron and hole;
a first electrode electrically connected from the second surface of the substrate to the first nitride compound semiconductor layer through the groove, and formed on the whole second surface of the substrate as a reflecting film; and
a second electrode electrically connected to the second nitride compound semiconductor layer.

12. A III-nitride compound semiconductor light emitting device, comprising:
a substrate with a groove formed therein;
a plurality of nitride compound semiconductor layers being grown over the substrate, and including an active layer for generating light by recombination of electron and hole; and
an opening formed on the groove along the plurality of nitride compound semiconductor layers.

13. The III-nitride compound semiconductor light emitting device of claim 12, comprising a first electrode electrically contacting the plurality of nitride compound semiconductor layers through the groove.

14. The III-nitride compound semiconductor light emitting device of claim 13, wherein the plurality of nitride compound semiconductor layers comprise a nitride compound semiconductor layer exposed by etching, and the first electrode electrically contacts the exposed nitride compound semiconductor layer.

15. The III-nitride compound semiconductor light emitting device of claim 12, wherein the substrate comprises a scribing line formed along the groove.

16. The III-nitride compound semiconductor light emitting device of claim 12, wherein the opening is formed on the scribing line.

17. The III-nitride compound semiconductor light emitting device of claim 12, comprising a step in the opening.

18. The III-nitride compound semiconductor light emitting device of claim 12, comprising a plurality of openings and a bonding pad positioned between the plurality of openings.

19. A III-nitride compound semiconductor light emitting device, comprising:
a substrate with a groove and a scribing line formed along the groove; and
a plurality of nitride compound semiconductor layers being grown over the substrate, and including an active layer for generating light by recombination of electron and hole.

20. The III-nitride compound semiconductor light emitting device of claim 18, comprising an opening formed over the groove along the plurality of nitride compound semiconductor layers.
